(19) United States
(12) Patent Application Publication
(10) Pub. No.: US 2021/0397977 A1
(43) Pub. Date: Dec. 23, 2021

(54) KNOWLEDGE MODEL CONSTRUCTION SYSTEM AND KNOWLEDGE MODEL CONSTRUCTION METHOD

(71) Applicant: Hitachi, Ltd., Tokyo (JP)

(72) Inventors: Yoshinari HORI, Tokyo (JP); Toshiaki KONO, Tokyo (JP); Takayuki UCHIDA, Tokyo (JP); Yasuharu NAMBA, Tokyo (JP)

(21) Appl. No.: 17/171,001

(22) Filed: Feb. 9, 2021

(30) Foreign Application Priority Data
Jun. 23, 2020 (JP) 2020-107554

(51) Int. Cl. G06N 5/02; G06N 20/00; G06N 7/00

(52) U.S. Cl. CPC G06N 5/022; G06N 7/005; G06N 20/00

(57) ABSTRACT

The knowledge model construction system includes: a CAD data which stores a design information including information on configurations of the parts; an input unit which inputs an element knowledge model which includes a plurality of combinations, each of the combinations being a combination of an element knowledge and an establishment condition thereof, the element knowledge representing a causal relationship with respect to an asset; a knowledge model construction unit which extracts a combination of an element knowledge applicable to an object asset and an establishment condition thereof by comparing the CAD data of the object asset with the establishment conditions of the element knowledge model; and an object asset knowledge model which records the extracted combination of the element knowledge and the establishment condition thereof as a knowledge model. Thus, the knowledge model construction system is able to construct a knowledge model of a new asset with less man-hours.

### CLAIM OF PRIORITY

The present application claims priority from Japanese Patent application serial No. 2020-107554, filed on Jun. 23, 2020, the content of which is hereby incorporated by reference into this application.

### BACKGROUND OF THE INVENTION

### Field of the Invention

The present disclosure relates to a system for constructing a knowledge model regarding assets and a method for constructing the knowledge model.

### Description of Related Art

In recent years, while the number of experienced workers has declined in various industrial fields, there is a movement to systematize knowledge on assets (i.e. various devices) and pass on and utilize it. And knowledge models which can explain a decision basis of an Artificial Intelligence (AI) have been utilized as commonplace with the increase of AI utilization. Hereinafter, “asset” is referred to as “a device or apparatus”.

The knowledge models can be represented in various ways. One of them is a method to represent knowledge shown by causal relations by directed graphs.

For example, Japanese Patent Application Laid-Open No. 2019-204302 (Patent Document 1) discloses a method including steps of representing a failure knowledge such as a failure of the assets by nodes, and representing by a directed graph connected between the nodes. By representing knowledge in such a directed graph in this way, the causal relationship of fragmentary knowledge can be traced, and it can be utilized for estimation of abnormal causes of assets and planning of countermeasures, etc.

Incidentally, since such a knowledge model depends on the part composition of the asset to be an object, there is a problem that it takes a long time to construct a knowledge model for each of the assets with different part configurations.

In Patent Document 1, the problem is solved by a maintenance work support system which includes: a failure knowledge database that records failure knowledge data such as asset failures; a failure knowledge coupling unit that reconstructs the partial failure knowledge data, which is the failure knowledge data created by being partially divided, as the failure knowledge data; and an investigation procedure generation unit that presents investigation procedures to maintenance workers using the reconstructed failure knowledge data, in which the failure knowledge coupling unit evaluates and adjusts relevance of description contents at each node between the different partial failure knowledge data, connects the different partial failure knowledge data, and reconstructs it as the failure knowledge data, and the investigation procedure generation unit sets a priority when presenting the investigation procedure to the maintenance worker from the reconstructed failure knowledge data, and presents the investigation procedure to the diagnostic interface unit based on the priority.

### SUMMARY OF THE INVENTION

By preparing partial failure knowledge data (partial failure knowledge) on a part-by-part basis in advance, as described in Patent Document 1, failure knowledge data of new assets, that is, knowledge models can be reconstructed according to the composition of parts.

However, depending on the parts that make up the assets, the product update cycle may be short and there are many parts variations. Therefore, it is necessary to reconstruct a new partial knowledge model for each part updated, and the construction man-hours increase. In addition, in the case of assets composed of very many parts, it may be difficult to judge whether a knowledge model should be constructed on a detailed part-by-part basis or a knowledge model should be constructed by considering a certain part group as a single “part”. In this case, it may take a great deal of man-hours to construct a partial knowledge model.

From the above, it is an object of the present disclosure to provide a knowledge model construction system and a knowledge model construction method that can construct a knowledge model of a new asset with less man-hours.

An aspect of embodiments in the present disclosure is a knowledge model construction system which constructs a knowledge model of assets composed of a plurality of parts. The knowledge model construction system includes: a CAD data which stores a design information including information on configurations of the parts; an input unit which inputs an element knowledge model which includes a plurality of combinations, each of the combinations being a combination of an element knowledge and an establishment condition thereof, the element knowledge representing a causal relationship with respect to an asset; a knowledge model construction unit which extracts a combination of an element knowledge applicable to an object asset and an establishment condition thereof by comparing the CAD data of the object asset with the establishment conditions of the element knowledge model; and an object asset knowledge model which records the extracted combination of the element knowledge and the establishment condition thereof as a knowledge model.

Another aspect of embodiments in the present disclosure is a knowledge model construction method which constructs a knowledge model of assets composed of a plurality of parts. The knowledge model construction method includes the steps of: inputting an element knowledge model which includes a plurality of combinations, each of the combinations being a combination of an element knowledge and an establishment condition thereof, the element knowledge representing a causal relationship with respect to an asset; extracting a combination of an element knowledge applicable to an object asset and an establishment condition thereof by comparing a CAD data of the object asset with the establishment conditions of the element knowledge model, the CAD data storing a design information including information on configurations of the parts; and recording the extracted combination of the element knowledge and the establishment condition thereof as a knowledge model.

The knowledge model construction system and the knowledge model construction method according to the embodiment of the present disclosure have an advantageous effect to be able to construct a knowledge model of a new asset with less man-hours.

### BRIEF DESCRIPTION OF THE DRAWINGS

FIG. 1 is a diagram illustrating an overall configuration of a knowledge model construction system according to Example 1.

FIG. 2 is a diagram illustrating an example of a CAD data.

FIG. 3 is a diagram showing an example of a part class diagram.

FIG. 4 is a table showing an example of an element knowledge model database.

FIG. 5 is a flowchart showing a processing in a knowledge model construction unit.

FIG. 6 is a table showing an information of a knowledge model displayed on a knowledge model display unit.

FIG. 7 is a diagram showing an information of a knowledge model displayed on the knowledge model display unit in the form of a directed graph.

FIG. 8 is a diagram showing an example of an image changed from the image shown as the diagram in FIG. 7.

FIG. 9 is a diagram illustrating an overall configuration of a knowledge model construction system according to Example 2.

FIG. 10 is a flowchart showing a modifying processing in the knowledge model modifying unit when there is a duplication in the constructed object asset knowledge model.

FIG. 11 is a diagram illustrating an example of a CAD data to be an object in the modifying processing.

FIG. 12 is a diagram illustrating a route of a causal relationship to be an object in the modifying processing.

FIG. 13 is a diagram illustrating an example of a screen in which a path is displayed on the knowledge model display unit.

FIG. 14 is a flowchart showing a shortage check processing in the knowledge model modifying unit when there is a shortage in the constructed object asset knowledge model.

FIG. 15 is a diagram illustrating an example of a CAD data to be an object in the shortage processing.

FIG. 16 is a diagram illustrating an example of knowledge extracted by the knowledge model construction unit.

FIG. 17 is a diagram illustrating an example of a virtual information of a CAD data.

FIG. 18 is a diagram showing a displayed image of an example in which a new part B3 is replaced with a higher-class part B.

FIG. 19 is a diagram showing an example of a screen for modifying an element knowledge model data so that an element knowledge is applicable to the part B3.

FIG. 20 is a diagram illustrating an overall configuration of a knowledge model construction system according to Example 3.

FIG. 21 is a table showing an example of a knowledge model including an added probability of the probabilistic knowledge model 10 in FIG. 20.

FIG. 22 is a flowchart showing an example of a processing when using the simulation unit 9 in FIG. 20.

FIG. 23 is a flowchart showing an example of the processing when using the probabilistic knowledge model 10 in FIG. 20.

### DETAILED DESCRIPTION OF THE PREFERRED EMBODIMENTS

Hereinafter, Examples of the present disclosure will be described with reference to the accompanying drawings.

### Example 1

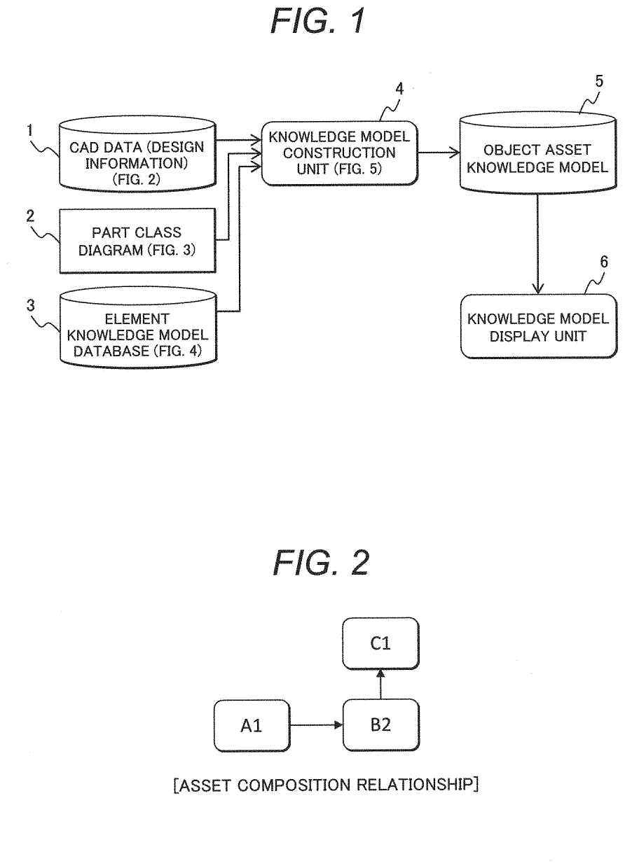

FIG. 1 is a diagram illustrating an overall configuration of a knowledge model construction system according to Example 1.

The knowledge model construction system of the present Example configured using a computer is composed of: an input unit for inputting element knowledge model data (Hereinafter, it is also simply referred to as an “element knowledge model”.) in a CAD data 1, a part class diagram 2 and an element knowledge model database 3; a knowledge model construction unit 4 for constructing a knowledge model using the input; a constructed object asset knowledge model 5; and a knowledge model display unit 6 for displaying the acquired knowledge model and various data. Herein, “CAD” is an abbreviation for “Computer-Aided Design”.

In addition, “information” may be used interchangeably with “data” in the present disclosure. And the CAD data 1 and the object asset knowledge model 5 may be referred to as a database, respectively.

Hereinafter, the construction of a knowledge model of an asset will be described using an example in which the asset is composed of parts A1, B2 and C1.

First, FIG. 2 shows an example of the CAD data 1.

The CAD data 1 stores a configuration diagram of the part together with a connection information as a design information (i.e., a design data). Herein, the configuration diagram of the part is stored as a digital data for drawing the part. According to the assets in the present example shown in FIG. 2, it can be seen that a configuration consisting of parts A1, B2 and C1, the part A1 is connected to B2, and the part B2 is connected to the part C1. In addition, the CAD data 1 may include operational conditions such as a design pressure and temperature of the asset in addition to the composition of the parts. In this example, information of design pressure 0.7 [MPa] and design temperature 80 [° C.] shall be assumed on all the parts.

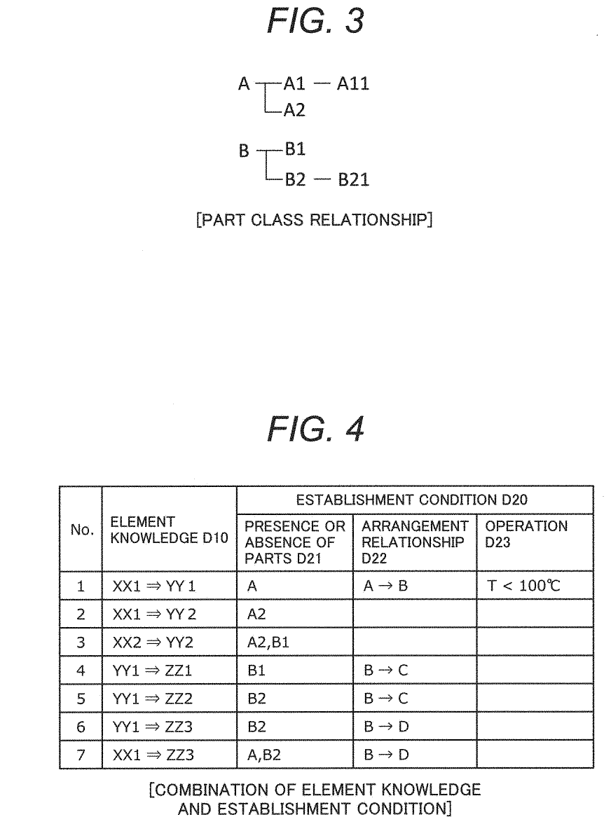

FIG. 3 shows an example of the part class diagram 2 of FIG. 1.

The part class diagram 2 is a hierarchical representation of a relationship between part names (part classes). In the example shown in FIG. 3, it is shown that a part A has types A1 and A2, and the part A1 has a type A11. Similarly, a part B has types B1 and B2, and the part B2 has a type B21.

FIG. 4 shows an example of an element knowledge model data in the element knowledge model database 3 of FIG. 1. The element knowledge model database 3 is a database for storing a knowledge model data relating to assets, and is represented by a combination of an element knowledge D10 and an establishment condition D20. The establishment condition D20 includes information on presence or absence of a part D21, an arrangement relationship D22, and an operation D23.

Of them, the element knowledge D10 is indicated by a causal relationship in which a causal side is estimated from a result side. For example, an example of the element knowledge of No. 1 of FIG. 4 is “XX1⇒YY1”, and it means that the cause is YY1 if the result is XX1. This causal relationship, for example, represents a relation between the cause of the failure and the symptom occurring. And it means that the cause is YY1 if a state (result) of XX1 is confirmed. It should be noted that the content represented by the element knowledge is not limited as long as it can be described as a causal relationship. For example, knowledge of the symptom and inspection items of the assets, or knowledge of the cause of the failure and its countermeasures may be used.

The establishment condition D20 is a condition under which the element knowledge D10 is established. In the present Example, “presence or absence of parts D21”, “arrangement relationship D22” and “operation D23” are set as the establishment conditions, but appropriate items can be set according to the type or the like of the asset.

The “presence or absence of parts D21” indicates a part which is indispensable for establishing the element knowledge. For example, “XX1→YY1” which is the element knowledge D10 of No. 1 shows that the part A is an indispensable part, and “XX1→YY2” which is the element knowledge D10 of No. 2 shows that the part A2 is an indispensable part.

Referring to the description matter of “presence or absence of parts D21” in FIG. 4 with the part class diagram shown in FIG. 3, there are several types of parts A, such as parts A1 and parts A2, but if the description of “presence or absence of parts D21” is “part A” as the establishment condition, any of the parts A1 and parts A2 satisfies the establishment condition. Conversely, if the statement “presence or absence of parts D21” is “part A1” as a condition for establishment, the assets using parts A2 do not satisfy the establishment conditions. Thus, even when there are many variations of parts, it is possible to manage knowledge efficiently by notation utilizing the part class diagram 2.

Incidentally, in this example, it describes the establishment conditions by a method of enumerating the corresponding parts by a comma divider, as shown in No. 3 of FIG. 4. This example means that it holds when there is a part A2 and there is a part B1. In this case, it may be represented the establishment condition by using symbols of a set, in order to define the establishment condition more strictly. For example, the establishment condition which is the content of No. 3 of FIG. 4 may be defined more strictly by representing it as “A2∩B1” (i.e. an intersection of A2 and B1). In the case of A2 or A11, it may be represented as “A2∪A11” (i.e. a union of A2 and A11). For example, when there are many types of a part E, that is, the part E includes types E1 to E7, and the part is established other than E7, it is possible to represent E1∪E2∪E3∪E4∪E5∪E6. Further, for example, it may describe the establishment conditions by representing E∩NOT(E7) in a simpler way.

The “arrangement relationship D22” is an arrangement relationship of parts for establishing the element knowledge D10. The example of the element knowledge at No. 1 of FIG. 4 is “A→B”, which defines that the part B must be located downstream of the part A. Thus, for example, if there is no part B and there is part C downstream of the part A, this element knowledge does not hold. Incidentally, in this example, the arrangement relationship has been shown by using “→” as a symbol indicating “upstream to downstream”.

Another representations indicating the establishment conditions of the arrangement relationship are the following examples:

It may be denoted as “A-B” that the part A is in contact with the part B.

Or the condition that the part A is above the part B may be denoted as “A/B”.

Also, there is no need to use a symbol, and it may be represented by using characters such as “A connected to B”.

“Operation D23” is an operation condition for establishing the element knowledge D10. For example, in the example of the element knowledge at No. 1 of FIG. 4, it is defined that it holds only when the operation temperature T is smaller than 100° C. In this case, only the conditions for achieving the operating temperature are described, but an operating condition such as “P>1 [MPa]” may be used for an operating pressure P. Also, the operation conditions may be denoted like “F>10 [times/h]” or “F<10 [times/day]” by using a use frequency F, etc. of the assets. As described above, “operation D23” can denote any operating condition related to the operation of the assets.

The knowledge model construction unit 4 extracts a knowledge model applicable to the object asset from the element knowledge D10 stored in the element knowledge model database 3 based on the information stored in the CAD data 1.

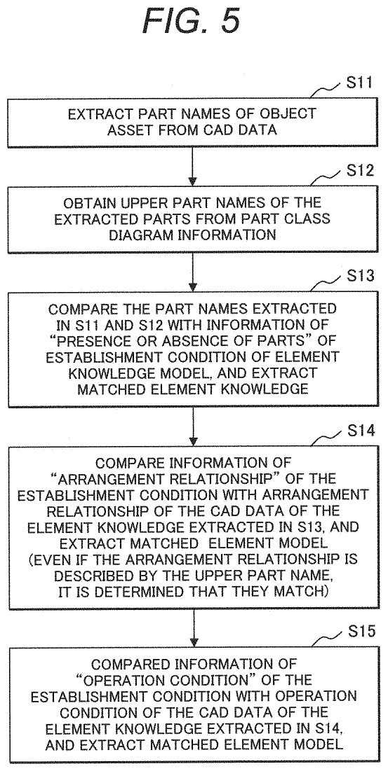

FIG. 5 is a flow diagram showing a processing in the knowledge model construction unit 4 of FIG. 1.

In a first processing step S11 of FIG. 5, part names of the object asset are extracted from the CAD data 1. As shown in FIG. 2, since the asset of the present example consist of parts A1, B2 and Cl, these parts A1, B2 and Cl are extracted in this step.

In the processing step S12, an upper part name of the extracted part is obtained from the information of the part class diagram. As shown in FIG. 3, the parts A and B are obtained as the upper part names of the parts A1, B2 and Cl in this step.

In the processing step S13, the part name extracted in the processing steps S11 and S12 is compared with the information of “presence or absence of parts D21” of the condition D20 for establishing the element knowledge model, and the matching element knowledge is extracted. When the available element knowledge is extracted under the condition of “presence or absence of parts D21” of the establishment conditions D20, in this example, since the parts A2 and B1 are the establishment conditions for the element knowledge No. 2, No. 3 and No. 4, these element knowledge No. 2, No. 3 and No. 4 do not match the object asset. Then, the element knowledge No. 1, No. 5, No. 6 and No. 7 remain.

In the processing step S14, of the element knowledge extracted in the processing step S13, the information of the “arrangement relationship D22” of the establishment condition D20 is compared with the arrangement relationship of the CAD data 1, and the matched element model is extracted. In this case, it shall be judged that the arrangement relationship matches even when it is denoted by the name of the upper part. In this example, when extracted under the establishment condition “arrangement relation D22”, No. 6 and No. 7 are “B D” and do not coincide with the object asset, and only No. 1 and No. 5 are extracted.

Finally, in the processing step S15, of the element knowledge extracted in the processing step S14, the information of the “operation condition D22” of the establishment condition D20 is compared with the operation condition of the CAD data 1, and the matched element model is extracted. The condition for establishing the “operation condition D22” is “T<100 [° C.]” and this is compared with the information of the object asset.

In the present example, as described above, the design temperature of both parts is 80° C., and satisfies the condition of less than 100° C. Therefore, the element knowledge of No. 1 and No. 5 is finally extracted as the knowledge model of the object assets.

As described above, the knowledge model of the object is constructed from the comparison with all the establishment conditions in the knowledge model construction unit 4.

The object asset knowledge model 5 is a knowledge model constructed by the knowledge model construction unit 4. In the present example, it consists of element knowledge of No. 1 and No. 5.

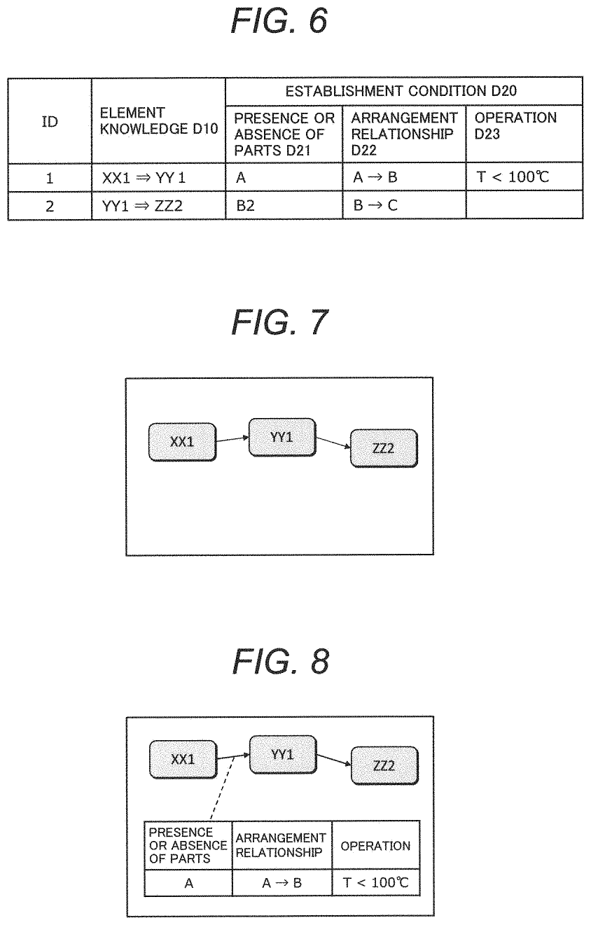

The knowledge model display unit 6 displays the object asset knowledge model 5. Examples of the display format are shown in FIGS. 6, 7 and 8.

The example of FIG. 6 is a tabular representation of the information of the knowledge model. The information of the extracted knowledge model is displayed under the same items as in FIG. 4. In the present example, the effect is difficult to understand because the number of element knowledge is small, but it is advantageous in the case of displaying by narrowing down the condition from a large amount of knowledge model, etc. by displaying it in the tabular representation.

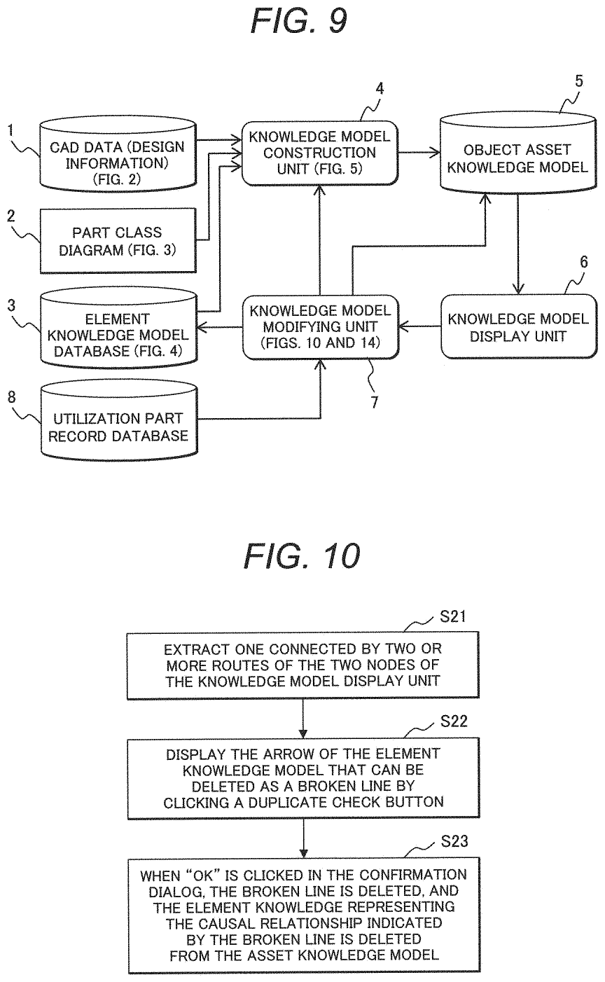

Next, another examples of the display format are shown in FIGS. 7 and 8. FIG. 7 shows an initial image on the screen and FIG. 8 shows an example of the image after the change from the image of FIG. 7.

In FIG. 7, the causal relationship of the element knowledges is displayed in the form of a directed graph. In the example of FIG. 6, there are two element knowledges of XX1 ⇒YY1 and YY1⇒ZZ2, and when this is combined, they can be represented in the form of the directed graph called XX1⇒YY1 ⇒ZZ2, as shown in FIG. 7. The whole knowledge model can be checked in a bird's-eye view by displaying it with the directed graph in this way.

In FIG. 7, only the element knowledge D10 is displayed, and the establishment condition D20 is not displayed, but in the present example, when the directed graph is clicked, the establishment condition D20 for establishing the element knowledge D10 is displayed. For example, as the image after the change in FIG. 8 is displayed when the arrow connecting XX1 and YY1 is clicked on the screen which the image of FIG. 7 is displayed, it is preferably configured to change the image on the screen so that the establishment condition is displayed.

As described above, in the present Example, since the knowledge model construction unit 4 can extract the object asset knowledge model 5 from the element knowledge model data in the element knowledge model database 3 by utilizing the CAD data 1 and the part class diagram. 2, the object asset knowledge model can be efficiently constructed. In addition, since the constructed object asset knowledge model 5 can be visualized by the knowledge model display unit 6, validity of the knowledge can also be confirmed.

In the present Example, the cases of utilizing the CAD data 1 including the configuration of the parts, the arrangement relationship such as connection or position, and the operating conditions has been explained. However, for example, a case such as the configuration information and the connection information is included in one CAD data 1 and the operating conditions are described in another design document, that is, the case that one item and another item are stored separately is allowable. Further, of the configuration of the parts, the connection information, and the operation condition, a case that data of the connection information and the operation condition do not exist is also allowable. In this case, it is better to construct the knowledge model of the object assets only by the information of parts existence because selection of the element knowledge by using the connection information and the operation condition is not possible in the knowledge model construction unit.

### Example 2

Next, Example 2 will be described.

FIG. 9 shows a configuration of the knowledge model construction system of Example 2.

Example 2 differs from Example 1 in that the knowledge model construction system of Example 2 includes a knowledge model modifying unit 7 and a utilization part record database 8 additionally.

The knowledge model modifying unit 7 will be described below.

The knowledge model modifying unit 7 modifies it when there is a duplication or shortage in the constructed object asset knowledge model.

First, an example of a case where there is the duplication will be described.

FIG. 10 is a flowchart showing a modifying processing in the knowledge model modifying unit 7 when there is a duplication in the constructed object asset knowledge model.

In the first processing step S21 of FIG. 10, one connected by two or more routes is extracted of the two nodes of the knowledge model display unit.

In the present Example, it is assumed that there is CAD data shown in FIG. 11 for the element knowledge model shown in FIG. 4. The asset shown in FIG. 11 consists of parts A1, B2, Cl and D. And the part A1 is connected to the part B2, the part B2 is connected to the part Cl and the part D is connected to the part B2. In addition, the CAD data 1 may include operational conditions such as a design pressure and temperature of the assets in addition to the composition of the parts.

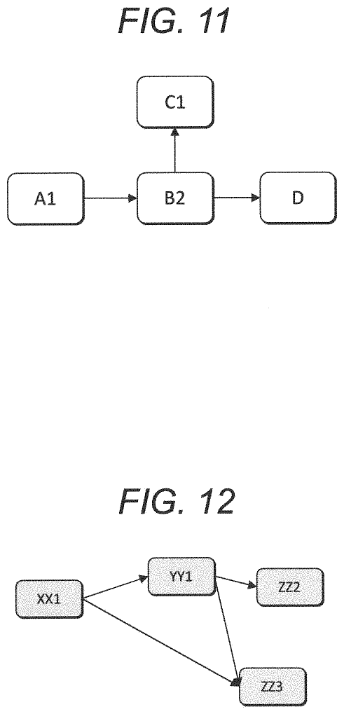

In this case, the causal relationship of the extracted object asset knowledge model is shown in the route of the causal relationship in FIG. 12. In FIG. 12, the three causal paths of XX1⇒YY1⇒ZZ2, XX1⇒YY1⇒ZZ3, XX1⇒ZZ3 are displayed.

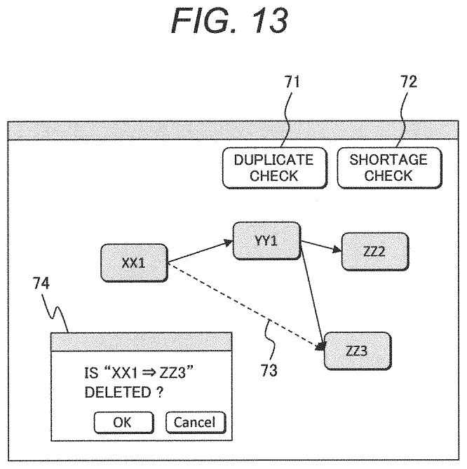

Further, a configuration example of a screen in which the path is displayed on the knowledge model display unit 6 is shown in FIG. 13, and operable check buttons, etc. are written together with the path shown in FIG. 12. Of these, two causal relationships leading from XX1 to ZZ3 are extracted: “XX1⇒ZZ3” represented directly, and “XX1⇒YY1⇒ZZ3” which is causal relationship via YY1. Since these are two descriptions of the same causality with two granularities (i.e., resolutions), one path 73 can be deleted.

The user who confirms the configuration of the route displayed on the screen of FIG. 13 displayed on the knowledge model display unit 6 deletes the path 73 (arrow) of XX1⇒ZZ3 by the knowledge model modifying unit 7.

Processing step S22 of FIG. 10 represents this process. The arrow of the element knowledge model that can be deleted is displayed as a broken line by pressing a duplicate check button.

Specifically, on the display screen of FIG. 13, by clicking the duplicate check button 71, the path 73 (arrow) of the element knowledge model that can be deleted becomes a broken line, and a dialog box 74 for confirming whether or not it can be deleted is displayed. When the OK button is clicked, the element knowledge of “XX1⇒ZZ3” is deleted from the object asset knowledge model 5, and path 73 (arrow) of the broken line is also deleted.

Processing step S23 of FIG. 10 corresponds to the above-described processing, that is, when OK is pressed in the confirmation dialog, the broken line is deleted, and the element knowledge representing the causal relationship indicated by the broken line is deleted from the asset knowledge model. If there are multiple duplicate element knowledges, the above processing is repeated multiple times. Thus, the duplicate element knowledge model is deleted.

Next, a case will be explained that the element knowledge model for the object assets is not sufficiently included in the element knowledge model database.

In the method shown in Example 1, the element knowledge related to the object assets is extracted from the element knowledge model database 3. Hence it is impossible to extract the element knowledge related to parts not included in the element knowledge model database 3. Although it is unavoidable when there are no similar parts in the past, it is possible to utilize the information of the element knowledge registered in the element knowledge model database if the parts used in the past are upgraded.

A concrete example is described below.

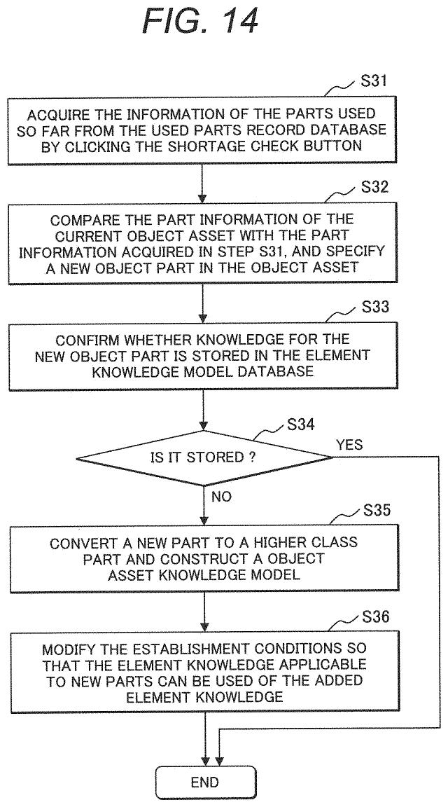

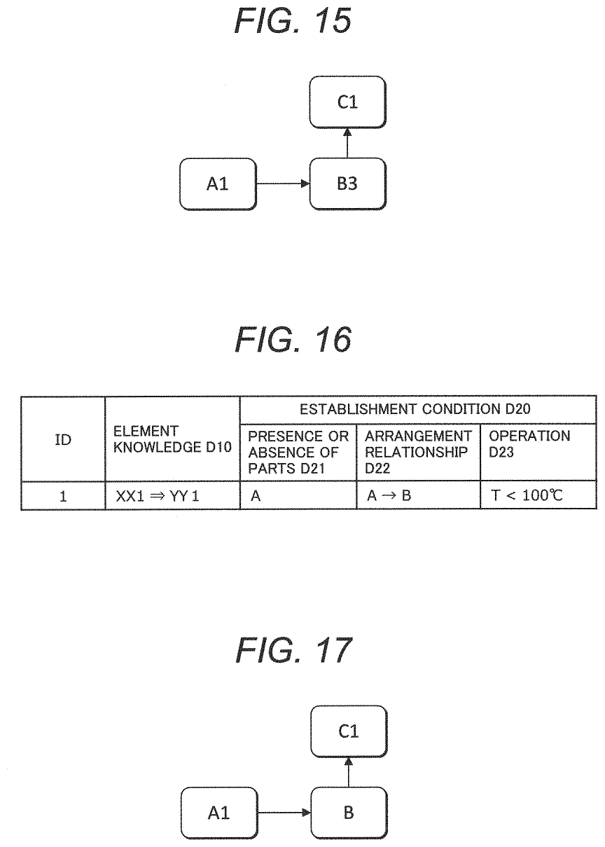

FIG. 14 is a flowchart showing a shortage check processing in the knowledge model modifying unit 7 of FIG. 9. In the case of the shortage check processing, it is assumed that the CAD data 1 to be an object is shown in FIG. 15. Compared with the example of FIG. 2, the parts change from B2 to B3.

In this instance, the knowledge extracted by the knowledge model constructing unit 4 is only “XX1⇒YY1” as shown in FIG. 16. When this is compared with FIG. 6, it does not include “YY1⇒ZZ2,” which is a knowledge of B2. This is because the knowledge about the part B3 is not stored in the element knowledge model database 3 in FIG. 4.

Therefore, in the present Example, by executing the following three processing steps S31, S32 and S33, checks whether there is insufficient knowledge.

In the first processing step S31 of FIG. 14, by clicking the shortage check button, information of the parts utilized so far is obtained from the utilization part record database 8 of FIG. 9. Incidentally, the shortage check button 72 is displayed on the screen of the knowledge model display unit, as shown in FIG. 13.

The information of the CAD data 1 used in the past is stored in the utilization part record database 8 of FIG. 9. All parts names registered in the element knowledge model database 3 are registered in the utilization part record database 8. Therefore, all the information of the parts that have been to be objects so far can be obtained.

In the processing step S32, the information of the parts of the current object asset is compared with the information of the parts obtained in the processing step S31, and the parts that have been to be objects newly are identified in the object asset. In this example, since the part B3 is a new part, the part B3 is listed as a new object part.

In the processing step S33, it is confirmed whether the knowledge for the new object part is stored in the element knowledge model database 3. Specifically, it is determined whether the character “B3” is included in the establishment condition D20 of FIG. 4 or not. In this example, there is no character “B3” in the element knowledge model database 3. Hence it can be seen that the element knowledge model for the part B3 may be insufficient.

In the processing step S34, it is determined whether the element knowledge model related to the part B3 is stored or not. And if it is stored, the processing is terminated. If it is not stored, in the processing step S35, and an addition processing of the element knowledge model is executed when a shortage is found.

In the present Example, first, element knowledge related to a higher-class part (a genus part) of the new part is utilized. The knowledge that is actually adaptable in the element knowledge is registered in the element knowledge model database.

Concrete procedures are described below.

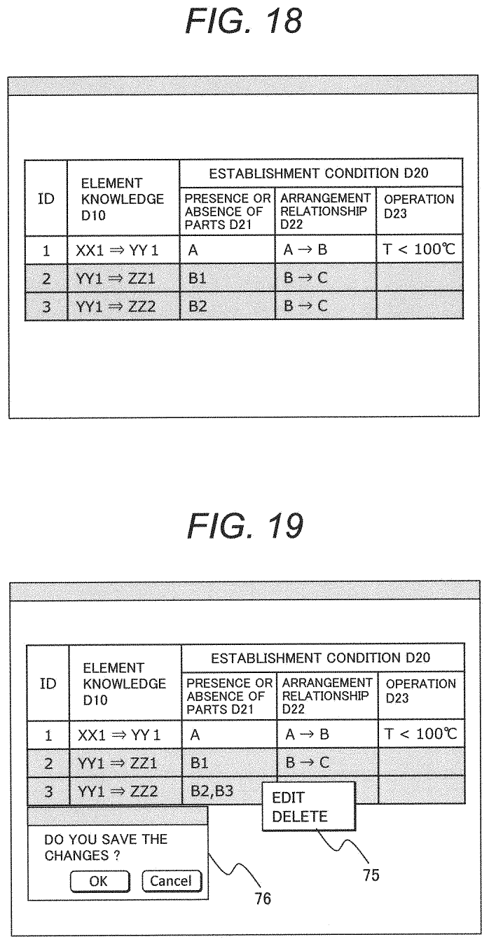

It is proven that there was a high possibility that knowledge on the part B3 was insufficient by this stage. Therefore, in the processing step S35, the object asset knowledge model is extracted on the assumption that the new part B3 is the “part B” which is a higher class. That is to say, the object asset knowledge model is constructed by utilizing an information of a virtual CAD data shown in FIG. 17. As is apparent by comparing FIG. 17 with FIG. 15, the new part B3 has been replaced by the higher-class part B. When the result is displayed by the knowledge model display unit 6, it is as shown in the screen of FIG. 18. Comparing FIG. 18 with FIG. 16, it can be seen that two knowledge models, hatched “YY1⇒ZZ1” and “YY1⇒ZZ2”, have been added.

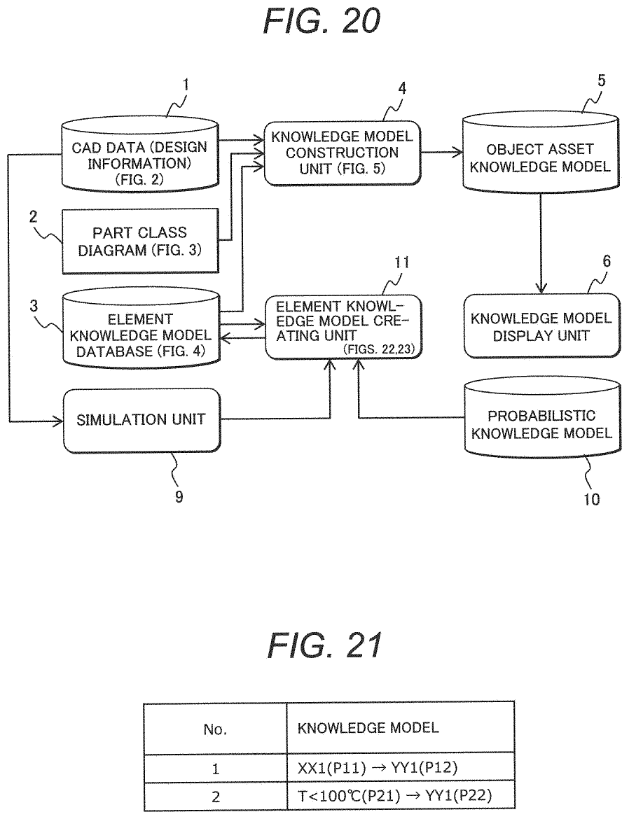

Of these, the knowledge that can also be utilized in the part B3 is newly added to the element knowledge model database 3. Therefore, in the processing step S36, the establishment condition is modified so that the element knowledge applicable to the new part can be used of the added element knowledge. Hereinafter, an exemplary modification will be described with reference to FIG. 19 so that “YY1⇒ZZ2” in which the element knowledge D10 having ID of 3 can be applied to the part B3.

When modifying the element knowledge D10 on the display screen of FIG. 19, the element to be modified is right-clicked and an operation menu 75 is called. You can edit the selected element knowledge by selecting “Edit” here. In this case, it is sufficient to change a column of the presence or absence of parts from “B2” to “B2, B3”, in order to modify the element knowledge to be available even in the part B3. When the information is changed, it is confirmed whether to save the changed contents in the dialog box 76, so that the element knowledge model database 3 is changed by clicking the OK button. By creating the object asset knowledge model 5 in the knowledge model construction unit 4 by using the element knowledge model database 3 after the change, the same model as in FIG. 6 can be constructed.

### Example 3

Finally, Example 3 will be described.

FIG. 20 shows an overall configuration of a knowledge model construction system according to Example 3.

Example 3 differs from Example 1 in that a simulation unit 9, a probabilistic knowledge model 10, and an element knowledge model creating unit 11 are newly provided. In addition, the probabilistic knowledge model 10 may be referred to as a database.

It will be described below, respectively.

Simulation unit 9 performs a simulation of the assets in cooperation with the CAD data 1. For example, if the asset is a plant, the characteristics in various operating conditions of the plant can be reproduced by simulation unit 9, based on the CAD data 1 of the plants.

The probabilistic knowledge model 10 (in other words, knowledge model with probability) stores the knowledge model adding probability thereto.

An example is shown in FIG. 21. In this example, the probability P11 of becoming XX1, and the probability P12 of becoming YY2 are stored separately from the knowledge model “XX1 ⇒YY1”. In this knowledge model, the probability P12 of becoming YY2 is changed by changing the probability P11 of becoming XX1, and the causal relationship can be represented more flexibly.

The element knowledge model creating unit 11 creates a new element knowledge model using the simulation unit 9, probabilistic knowledge model 10 that is another type knowledge model, and the element knowledge model database 3.

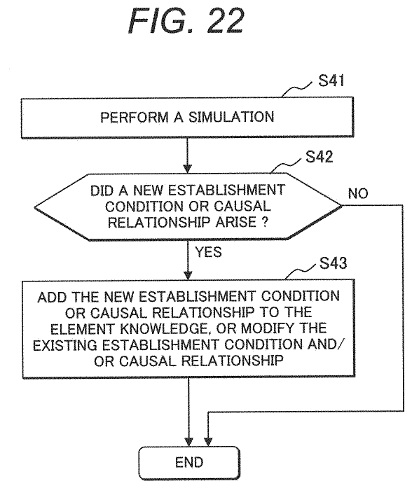

First, an example of a processing when using the simulation unit 9 will be described with reference to FIG. 22.

In the processing flow of FIG. 22, first, a simulation is performed in a processing step S41, and the simulation results are obtained.

Next, in a processing step S42, as a simulation result, it is determined whether a new establishment condition or causal relationship is found or not. In a state where a new establishment condition or causal relationship is not known, the subsequent processing is not performed. On the other hand, when a new establishment condition or causal relationship is found, a processing step S43 is performed. In the processing step S43, at least one of a new establishment condition and causal relationship are added to the element knowledge, or at least one of the existing establishment condition and causal relationship are modified.

For example, focusing on the knowledge “XX1⇒YY2” of No. 2 in the element knowledge D10 of FIG. 4 as a specific example of the above process, only the condition D20 that the presence or absence of parts D21 is the part “A2” is shown here. However, for example, when the operating temperature T is 80° C. or higher, it may be seen that the causal relationship of “XX1⇒YY2” is not established by the simulating unit 9. In such cases, “T<80 [° C.]” is a requirement that the causal relationship “XX1⇒YY2” holds. In the processing step S42, this point of view is extracted as a new establishment condition or causal relationship from the simulation result. And the processing step S43 is executed.

In the processing step S42, therefore, an item “T<80 [° C.]” is added as an item of “operation D23” of the establishment condition D20, and the accuracy of the element knowledge can be improved. When the part is changed to “A3” and simulated, if it is found that the part is “XX1⇒YY3” instead of “XX1⇒YY2”, new knowledge of the element knowledge “XX1⇒YY3” and the “A3” can be added to the establishment condition “presence or absence of parts D21”.

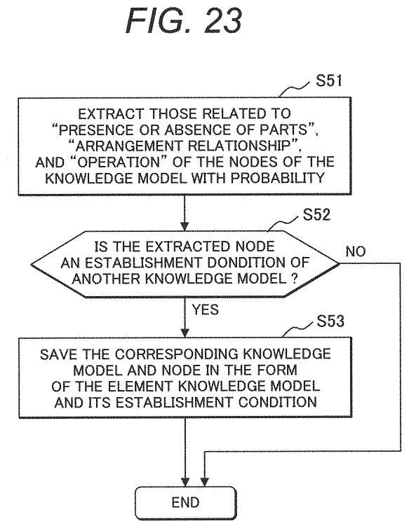

Next, an example in a case of utilizing the probabilistic knowledge model 10 will be described with reference to FIG. 23.

When the probabilistic knowledge model 10 is used, one corresponding to the establishment condition of the knowledge included in the probabilistic knowledge model 10 is saved in the form of the element knowledge model database 3, and a new element knowledge model is created.

In the processing flow of FIG. 23, first, in a processing step S51, those relating to the “presence or absence of parts”, “arrangement relationship” and “operation” of the nodes of the probabilistic knowledge model 10 are extracted.

Specifically explained with reference to the example of FIG. 21, those relating to “presence or absence of parts”, “arrangement relationship” and “operation” of those described as nodes (both ends of “→”) of the probabilistic knowledge model 10 are extracted.

Next, in a processing step S52, it is confirmed whether the extracted node is the establishment condition of the other knowledge model or not. When it is an establishment condition, a processing step S53 is executed. If not, the processing ends.

Next, in the processing step S53, the corresponding knowledge model and nodes are stored in the form of an element knowledge model and its establishment conditions. Thereby, if it is an establishment condition of another knowledge model, it can be extracted as another knowledge model plus its establishment condition.

For example, of the knowledge models shown in FIG. 21, “T<100 [° C.]” is the operating condition. Hence it becomes a candidate of the establishment condition. However, if this is not “T<100 [° C.]”, it is necessary that the “XX1⇒YY1” is not satisfied.

In the example shown in FIG. 21, “T<100 [° C.]” becomes the establishment condition of “XX1⇒YY1”, when the probability P12 of YY1 is zero or sufficiently small even if the probability P21 of “T<100 [° C.]” is zero or sufficiently small value and the probability P11 of XX1 is 1 or sufficiently large value.

In this way, the two probabilistic knowledge models shown in FIG. 21 are converted to the knowledge of element knowledge No. 1 in FIG. 4.

As described above, according to the present Example, a new element knowledge model can be created by the simulation unit 9, the probabilistic knowledge model 10 and the element knowledge model creating unit 11.

Incidentally, in Examples 1 to 3, the probability that the causal relationship is established has not been added to the element knowledge model in order to explain it simply, but such a probability may be added to each of the element knowledge model.

### DESCRIPTION OF REFERENCE NUMERALS

1: CAD data, 2: part class diagram, 3: element knowledge model database, 4: knowledge model construction unit, 5: object asset knowledge model, 6: knowledge model display unit, 7: knowledge model modifying unit, 8: utilization part record database, 9: simulation unit, 10: probabilistic knowledge model, 11: element knowledge model creating unit.

What is claimed is:

1. A knowledge model construction system which constructs a knowledge model of assets composed of a plurality of parts, the knowledge model construction system comprising:
a CAD data which stores a design information including information on configurations of the parts;
an input unit which inputs an element knowledge model which includes a plurality of combinations, each of the combinations being a combination of an element knowledge and an establishment condition thereof, the element knowledge representing a causal relationship with respect to an asset;
a knowledge model construction unit which extracts a combination of an element knowledge applicable to an object asset and an establishment condition thereof by comparing the CAD data of the object asset with the establishment conditions of the element knowledge model; and
an object asset knowledge model which records the extracted combination of the element knowledge and the establishment condition thereof as a knowledge model.

2. The knowledge model construction system according to claim 1,
wherein the input unit inputs a part class diagram which is a hierarchical representation of a relationship between part names,
the establishment condition includes an information on presence or absence of parts, an arrangement relationship and an operation.

3. The knowledge model construction system according to claim 1,
wherein the knowledge model is represented in a tabular form or a directed graph form.

4. The knowledge model construction system according to claim 1,
further comprising a knowledge model modifying unit which modifies it when there is a duplication or shortage in the constructed object asset knowledge model.

5. The knowledge model construction system according to claim 1, further comprising:
a simulation unit;
a probabilistic knowledge model; and
an element knowledge model creating unit,
wherein the simulation unit performs a simulation using the CAD data,
and when a new establishment condition or causal relationship is obtained as a result of the simulation, the element knowledge model creating unit uses the result for a new element knowledge model.

6. The knowledge model construction system according to claim 5,
wherein the probabilistic knowledge model includes an information on presence or absence of the parts, an arrangement relationship and an operation,
the element knowledge model creating unit extracts nodes relating to the presence or absence of the parts, the arrangement relationship and the operation of the nodes of the probabilistic knowledge model,
confirms whether the extracted nodes are establishment conditions of other knowledge models or not,
saves the corresponding knowledge model and node in the form of the element knowledge model and the establishment condition thereof, and adds them to the element knowledge model when the extracted nodes are the establishment conditions.

7. A knowledge model construction method which constructs a knowledge model of assets composed of a plurality of parts, the knowledge model construction method comprising the steps of:
inputting an element knowledge model which includes a plurality of combinations, each of the combinations being a combination of an element knowledge and an establishment condition thereof, the element knowledge representing a causal relationship with respect to an asset;
extracting a combination of an element knowledge applicable to an object asset and an establishment condition thereof by comparing a CAD data of the object asset with the establishment conditions of the element knowledge model, the CAD data storing a design information including information on configurations of the parts; and
recording the extracted combination of the element knowledge and the establishment condition thereof as a knowledge model.

8. The knowledge model construction method according to claim 7,
wherein the inputting step includes inputting apart class diagram which is a hierarchical representation of a relationship between part names,
wherein the establishment condition includes an information on presence or absence of parts, an arrangement relationship and an operation.

9. The knowledge model construction method according to claim 7,
wherein the knowledge model is represented in a tabular form or a directed graph form.

10. The knowledge model construction method according to claim 7,
further comprising a step of modifying it when there is a duplication or shortage in the constructed object asset knowledge model.

11. The knowledge model construction method according to claim 7, further comprising the steps of:
performing a simulation using the CAD data; and
using the result for a new element knowledge model when a new establishment condition or causal relationship is obtained as a result of the simulation.

12. The knowledge model construction method according to claim 7, further comprising the steps of:
extracting nodes relating to the presence or absence of the parts, the arrangement relationship and the operation of the nodes of a probabilistic knowledge model;
confirming whether the extracted nodes are establishment conditions of other knowledge models or not; and
saving the corresponding knowledge model and node in the form of the element knowledge model and the establishment condition thereof, and adding them to the element knowledge model when the extracted nodes are the establishment conditions,
wherein the probabilistic knowledge model includes an information on presence or absence of the parts, an arrangement relationship and an operation.
